(19) United States
(12) Patent Application Publication
(10) Pub. No.: US 2015/0327404 A1
(43) Pub. Date: Nov. 12, 2015

(54) Heat transfer component with dendritic crystal structures and purpose and method of use for such a component

(71) Applicant: Far East University, Tainan City (TW)

(72) Inventors: Jenn-Shing Wang, Tainan City (TW); Yu-Ching Wang, Tainan City (TW); Jia-Yu Wu, Tainan City (TW)

(21) Appl. No.: 14/569,620

(22) Filed: Dec. 12, 2014

(30) Foreign Application Priority Data
May 6, 2014 (TW) 103116106

(51) Int. Cl. H05K 7/20

(52) U.S. Cl. CPC H05K 7/20509

(57) ABSTRACT

A heat transfer component with dendritic crystal structures and a purpose and method of use for such a component; this component is used to resolve the deficiency concerning conventional heat transfer components possessing inadequate surface areas for heat dissipation. Dendritic crystal structure is comprising: a substrate and multiple dendritic crystals. The substrate contains multiple preset crystal defects in which all the dendritic crystals deposit and congregate, and a space is located between each dendritic crystal for thermal convection. Regarding the method of use, the substrate is connected to a heat source, which then induces directional heat transfer from the substrate and the metal layer to the main branch and at least one sub-branch of the dendritic crystal, or the dendritic crystal is placed on a heat source, which induces heat transfer from the crystal to the substrate.

### BACKGROUND OF THE INVENTION

1. Field of the Invention

The present invention relates to a heat transfer component with dendritic crystal structures and its purpose and method of use; in particular, using dendritic crystals formed through metal ion deposition as a heat transfer component. The dendritic crystals differ from the whiskers that grow from metal because of internal stress.

2. Description of the Related Art

Lightweight and thin electronic devices are growing in popularity; thus, relevant industrial operators have endeavored to devise a method of rapidly and effectively cooling electronic devices using small heat transfer components.

Commonly used heat transfer components are composed of copper or aluminum metal substrate that has excellent thermal conductivity. In addition, a heat sink is placed on the substrate to dissipate the heat generated by the cooling electronic device into the surrounding environment. However, the surface area on the heat sink and metal substrate is limited, rendering enhancing the efficiency of heat dissipation difficult.

Several industrial operators have used whiskers, which were initially regarded as defects produced during electroplating, as heat transfer components for use in heat pipe components. Related patents include “Heat sink for electric and/or electronic devices” (European patent No. EP0999590), “Heat transfer between solids and fluids utilizing polycrystalline metal whiskers” (U.S. Pat. No. 3,842,474), and “Heat Dissipation Structure in Cooling Devices” (Taiwan patent No. 201326718).

However, the aforementioned whiskers are growth induced by the residual internal stress released from the electroplating layer. This mechanism not only involves slow growth, but also requires lengthy preparation time. Furthermore, whiskers typically exhibit a rod shape with narrow diameter and monocrystalline form and, thus, cannot provide additional grain boundary area. Therefore, whiskers also provide limited surface area for heat dissipation, yielding poor heat dissipation effect.

Dendritic crystals are another type of defect commonly observed in electroplating. These crystals are produced during the process of electroplating, in which the current focusing effect influences the deposition of the metal ions on the protuberance of the substrate, causing growth of tree-like crystals. These tree-line crystals severely influence the smoothness and aesthetics of the electroplated product and thus are often viewed as a defect that should be prevented.

For example, in 2008, Yi-da Tsai from the National Chung Chen University mentioned in his master's dissertation, titled “Electrodeposition of Sn—Bi Lead-Free Solders: Effects of Complex agents on the Composition Control, Adhesion, and Dendrite Formation,” that previous studies showed Sn—Bi alloys prepared by electrodeposition to exhibit unsatisfactory adhesion and dendrite formation. Therefore, complex agents or surfactant must be added to reduce the growth of dendrites. Consequently, scholars in the field of electroplating still regard dendritic crystals as a defect that yields no specific effect.

### SUMMARY OF THE INVENTION

Therefore, for improving the limited heat dissipation surface area provided by conventional heat dissipating components, a heat transfer component with dendritic crystals is proposed. This component comprises a substrate, on top of which contains multiple predetermined crystal defects. Numerous dendritic crystals are deposited onto these crystal defects, and a space is located between each crystal for thermal convection.

Further, the aforementioned dendritic crystals possess a main branch connected to a sub-branch.

Further, the aforementioned crystal defect is any one of or a combination of a whisker, protrusion, burr, and an edge.

Further, the density of the aforementioned dendritic crystals on the substrate is 3-15 dendritic crystal/cm2.

Further, the length of the aforementioned dendritic crystals is 0.1-15 mm.

Further, the length of the aforementioned dendritic crystals is 1-5 mm.

Further, the aforementioned space has a length of 0.1-15 mm.

And includes an antioxidant layer that covers the aforementioned substrate and dendritic crystals.

This invention is also an object that provides the purpose of a heat transfer component possessing dendritic crystals. It involves placing at least one dendritic crystal on the substrate and then connecting the substrate to a heat source to induce directional heat transfer from the substrate to the dendritic crystal or placing the dendritic crystal by a heat source to induce heat transfer from the heat source through the dendritic crystal to the substrate.

It is also an object that provides a method of use for a heat transfer component possessing dendritic crystals. It involves placing at least one dendritic crystal on the substrate and then executing the following method: place the substrate on a heat source to induce heat transfer from the heat source through the substrate to the dendritic crystal or place the dendritic crystal by a heat source to induce heat transfer from the heat source through the dendritic crystal to the substrate.

### The Effect of this Invention

1. Dendritic crystals have been viewed as a defect in traditional electroplating; however, this biased viewpoint is negated through the present invention, in which dendritic crystals are used in a heat transfer component to provide directional heat transfer. In addition, the fractal structures on the dendritic crystals provide additional surface area for heat dissipation, thereby improving the efficiency of heat dissipation.

2. The present invention involves using whiskers or cutting processing to produce crystal defects required for the growth of dendritic crystals. These crystal defects facilitate dendritic crystal growth and the control of the location at which the dendritic crystals grow on the substrate, thereby increasing the practical value of the present invention.

3. The present invention involves using whiskers as crystal defects, enabling dendritic crystals to closely and firmly grow on the substrate, thereby further enhancing the heat dissipation efficiency of the dendritic crystals.

4. The present invention involves the presence of spacing between each dendritic crystal that is used as the space for thermal convection to prevent heat deposition and ensure the heat dissipation effect of the dendritic crystals.

5. Multiple dendritic crystals with a length of 1-5 mm and spacing of 0.1-5 mm exhibited optimal heat dissipation effect.

### BRIEF DESCRIPTION OF THE DRAWINGS

FIG. 1 is a flowchart illustrating the embodiment of the steps of growing dendritic crystals according to the present invention.

FIG. 2 is a flowchart illustrating the embodiment of the procedure for growing dendritic crystals according to the present invention.

FIG. 3A is a diagram showing the embodiment of the dendritic crystals observed at various magnifications using the scanning electron microscope (SEM).

FIG. 3B is a microscopic image no. 1 displaying the embodiment of the dendritic crystals observed at 450× magnification under an optical microscope.

FIG. 3C is a microscopic image no. 2 displaying the embodiment of the dendritic crystals observed at 450× magnification under an optical microscope.

FIG. 3D is a microscopic image no. 3 displaying the embodiment of the dendritic crystals observed at 450× magnification under an optical microscope.

FIG. 4A is a computer image no. 1 displaying the embodiment of the whiskers according to the present invention.

FIG. 4B is an electron microscope image no. 2 displaying the embodiment of the whiskers according to the present invention.

FIG. 4C is an electron microscope image no. 3 displaying the embodiment of the whiskers according to the present invention.

FIG. 4D is an electron microscope image no. 4 displaying the embodiment of the whiskers according to the present invention.

FIG. 5 is a schematic diagram of the embodiment of the substrate comprising drilled holes with burrs according to the present invention.

FIG. 6 is a schematic diagram of the embodiment of the dendritic crystals grown at the edge of the substrate according to the present invention.

FIG. 7 is a schematic diagram of the embodiment of the actual sample according to the present invention.

FIG. 8 is a thermal image of the embodiment of FIG. 7 according to the present invention.

FIG. 9 is a graph showing the embodiment of a comparison of various test specimens exposed to the same heat source (LED light) for 30 minutes according to the present invention.

FIG. 10 is a thermal image showing the embodiment of the hot-air conditions on the surface of the dendritic crystals according to the present invention.

FIG. 11 is a temperature curve illustrating the embodiment of the surface of the dendritic crystals according to the present invention.

FIG. 12 is a thermal image showing the embodiment of heat transfer occurring in a 3-mm single dendritic crystal according to the present invention.

FIG. 13 is a temperature curve illustrating the embodiment of the heat transfer occurring in a 3-mm single dendritic crystal according to the present invention.

FIG. 14 is a thermal image showing the embodiment of heat transfer occurring in a 0.75-mm single dendritic crystal according to the present invention.

FIG. 15 is a temperature curve illustrating the embodiment of the heat transfer process in a 0.75-mm single dendritic crystal according to the present invention.

FIG. 16 is a thermal image showing the embodiment of heat transfer occurring in the area between two dendritic crystals according to the present invention.

FIG. 17 is a temperature curve illustrating the embodiment of the heat transfer occurring in the area between two dendritic crystals according to the present invention.

FIG. 18 shows various forms of dendritic crystals formed by using different deposition parameters.

FIG. 19 shows various forms of dendritic crystals formed by using different deposition parameters.

FIG. 20 shows various forms of dendritic crystals formed by using different deposition parameters.

FIG. 21 shows various forms of dendritic crystals formed by using different deposition parameters.

### DETAILED DESCRIPTION

Based on the technical characteristics described above, the embodiments of the primary effects of the present invention, that is, the purpose and method of using dendritic crystals for heat transfer, are described below.

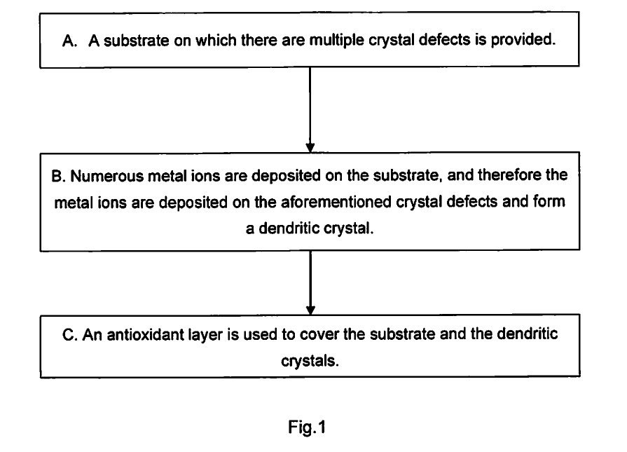

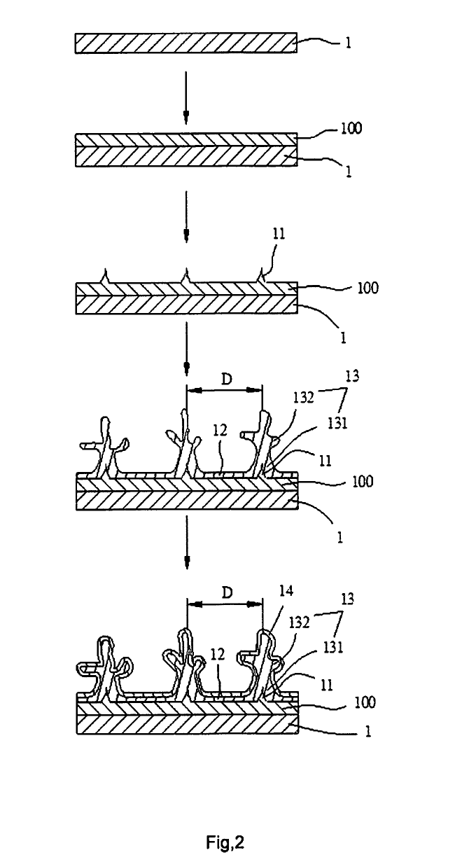

Referring to FIGS. 1 and 2, the embodiment of the dendritic crystal structures used for directional heat transfer, the flowchart of the preparation procedures, and the flowchart of the preparation process are revealed.

A. A substrate (1) is provided, and the substrate (1) contains multiple crystal defects (11). Crystal defect (11) in the present invention is defined as encompassing whiskers as well as point and line defects that exhibit crystal structures with destroyed regularity. The preferred substrate (1) is a metal (e.g., copper or aluminum) featuring high electrical conductivity and thermal conductivity. The substrate is preprocessed by using a degreasing procedure and a sensitization procedure, which entails immersing the substrate in acidic solution to enhance the adhesive effect of the aforementioned metal ion during electroplating.

Specifically, substrate (1) is not limited to electrical-conductive material; it can be materials with no electrical conductivity such as plastic or ceramics. When the substrate (1) is plastic or ceramics, it must be subjected to procedures such as chemical corrosion and surface activation; these procedures are prior art and, thus, are not described in detail.

Preferably, a cover that has low electrical conductivity is placed on a predetermined location on the substrate, preventing the growth of the subsequent dendritic crystals (13) at the predetermined location. For example, the substrate (1) can be surrounded by a stainless steel sheet.

B. The substrate (1) is used as the electrode for electroplating to facilitate using deposition to deposit metal ions onto the substrate (1), forming a metal layer (12). The aforementioned metal ions will form a dendritic crystal (13) on the aforementioned crystal defects (11) because of the effect of current focusing. Particularly, the aforementioned metal layer (12) does not necessarily have to completely cover the substrate (1); the principle behind the effect of current focusing can be applied to grow dendritic crystals (13) independently. Deposition methods such as electrochemical plating, physical vapor deposition (PVD), and chemical vapor deposition (CVD) are all feasible approaches. The embodiment of the present invention is illustrated using electrochemical plating.

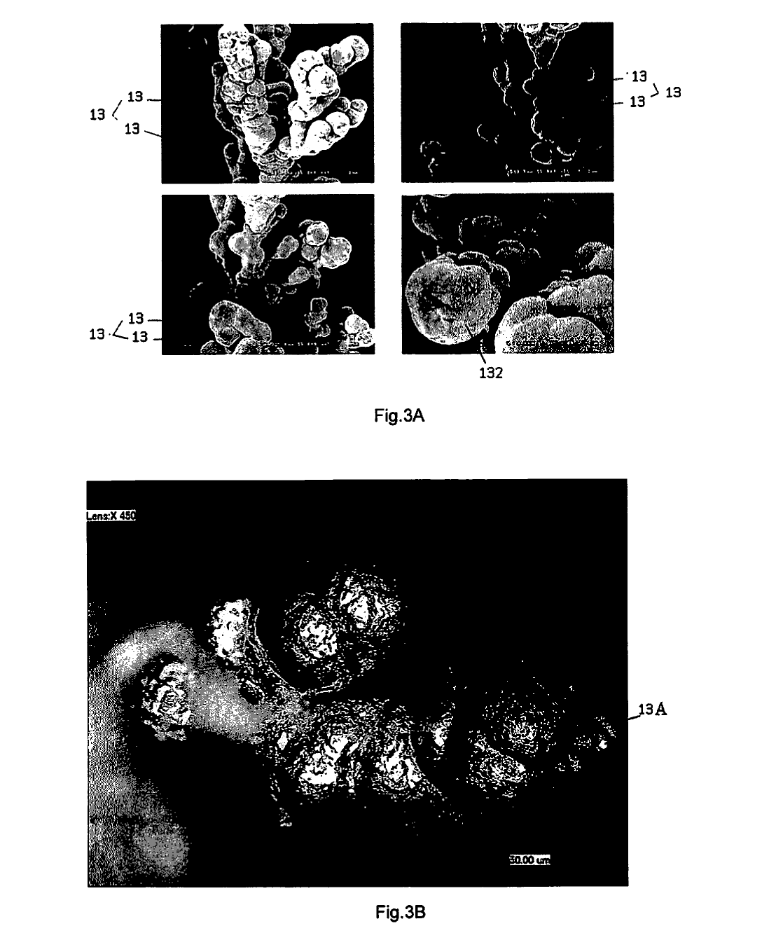

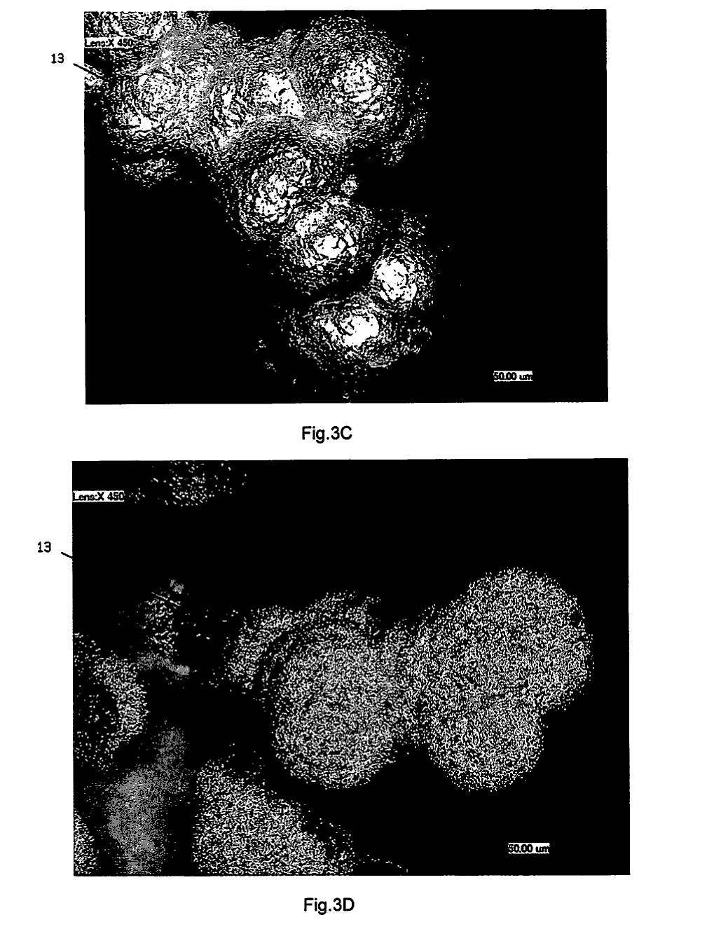

FIG. 3A is a diagram showing the outer appearance of the dendritic crystals (13) observed at various magnifications using the SEM. The dendritic crystals (13) comprise a main branch (131) to which at least one sub-branch (132) is attached. Preferably, the density of the aforementioned dendritic crystals (13) on the substrate (1) is 3-15 dendritic crystal/cm2, the length of the aforementioned dendritic crystals (13) is 0.1-15 mm, the length of the aforementioned dendritic crystals (13) is 1-5 mm, and each dendritic crystal (13) has a space (D) between each other, the space (D) is preferably at least 0.1-15 mm. In particular, the ratio of the height of the dendritic crystals to the length of the cross-sectional diagonal line is greater than 2 to provide sufficient space for heat exchange and avoid resulting in heat deposition. Specifically, the electric current density of electroplating is 1-5 A/dm2, and the duration of the aforementioned electroplating is 60-180 min.

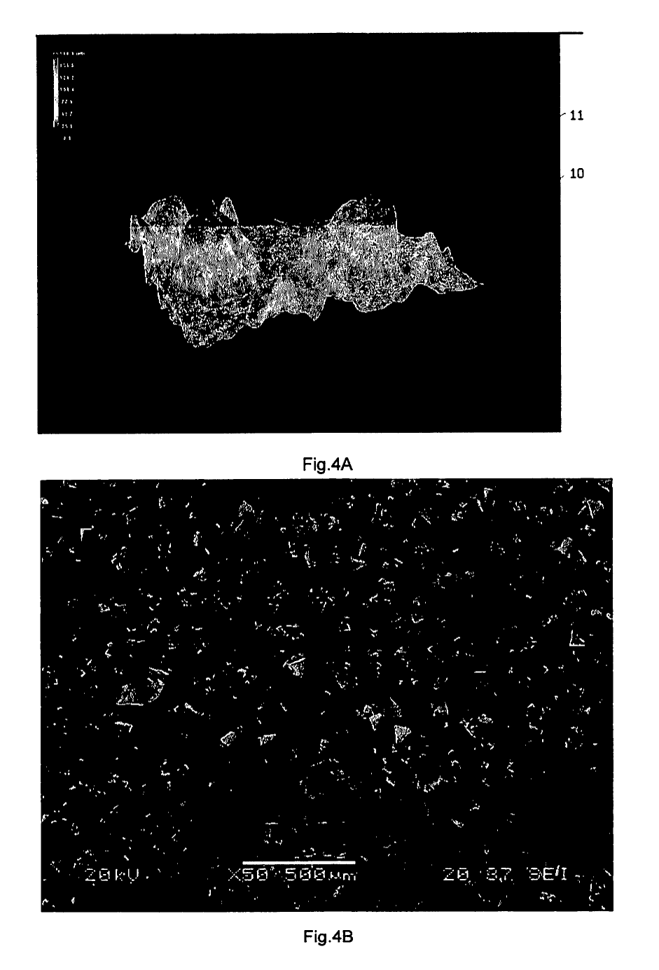

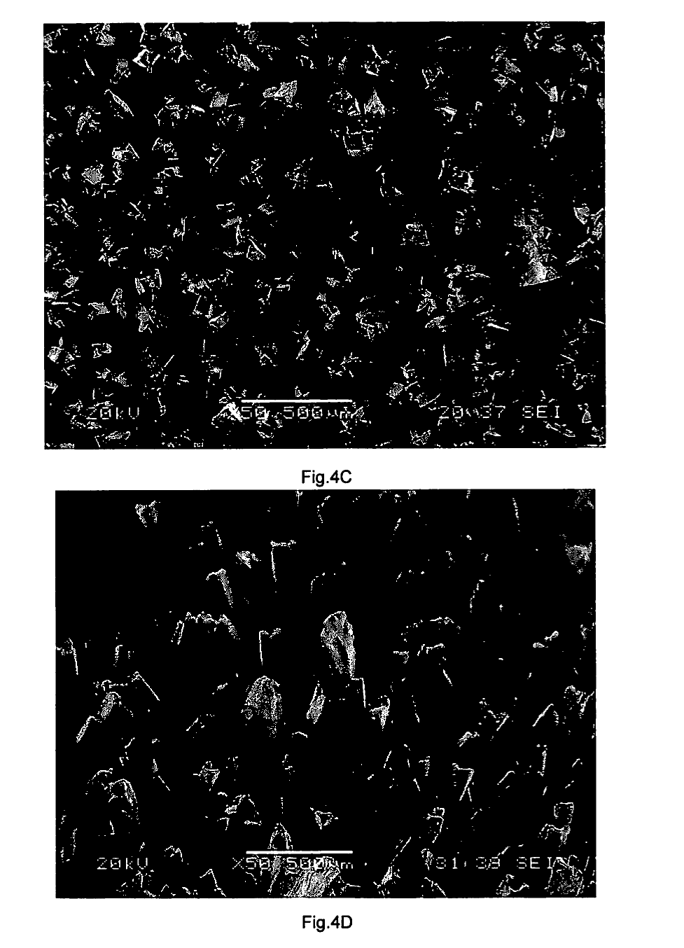

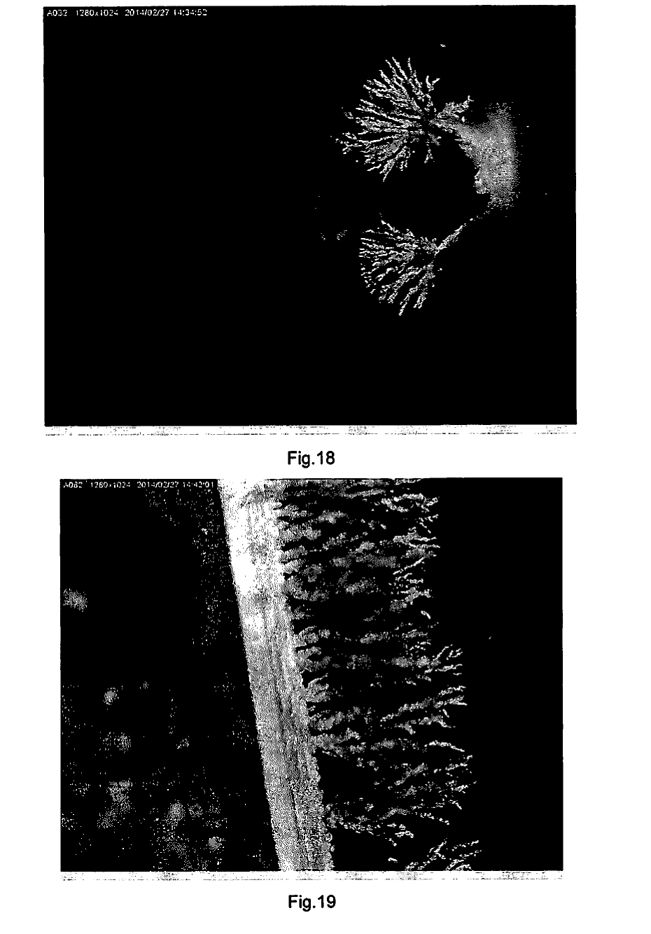

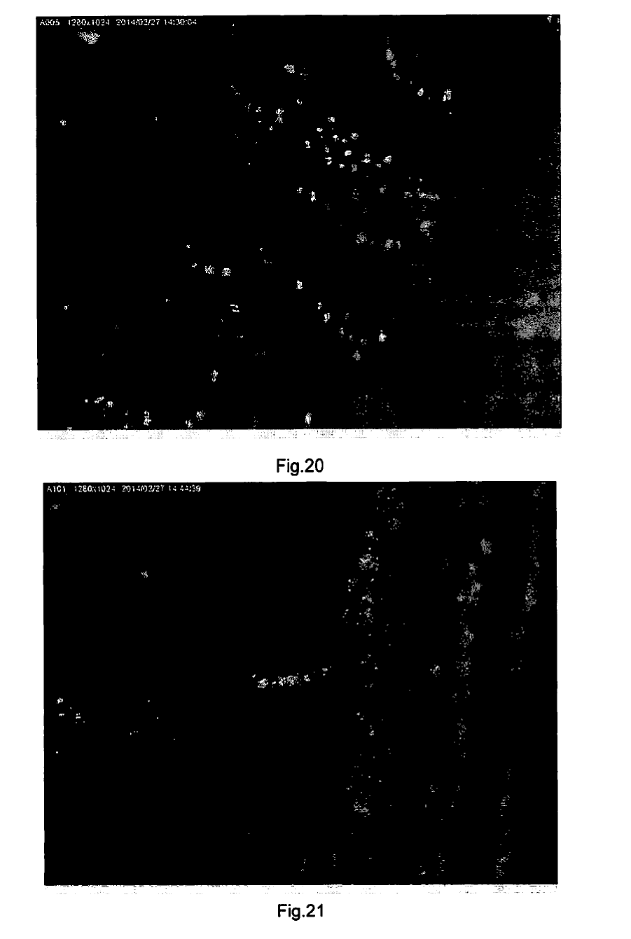

FIGS. 3B to 3D illustrate the outer appearance of the dendritic crystals (13A, 13B, 13C, 13D) observed at 450× magnification under an electron microscope. The electroplating condition is as follows: temperature of 30° C.-60° C., duration of 2 hr, electric current of 2.8-8 A/dm2, and electroplating solution of copper-containing electroplating solution with pH of 0-2.5; in particular, optimal copper-containing electroplating solution is at pH 1.45 with a specific weight of 1.190 to form copper dendritic crystals (13A, 13B, 13C, 13D) featuring superior strength and heat dissipation effect. FIGS. 18 to 21 display the overall forms (radial e.g., FIGS. 1 and 2 and columnar e.g., FIGS. 3 and 4) of the dendritic crystals developed using various parameters. Thus, dendritic crystals are not limited to having a main branch and sub-branch form; columnar dendritic crystals are also feasible.

Referring to FIG. 4A, preferably, in Step A, the substrate (1) is deposited with a layer of whiskers (100), and the whisker layer (11) comprises any one or a combinations of tin, cadmium, zinc, antimony, and indium, all of which exhibit low hardness and favorable ductility. Therefore, these metals are effective for growing whiskers on the substrate (1) that are useful to the aforementioned crystal defects (11) when releasing internal stress, generating dendritic crystals (14) that possess a substantial binding strength. FIGS. 4B to 4D display whiskers of various forms observed at a magnification of 50× under a SEM. Although the whiskers are distinct in form, they are generated by the internal stress released from the high-ductile whisker layer.

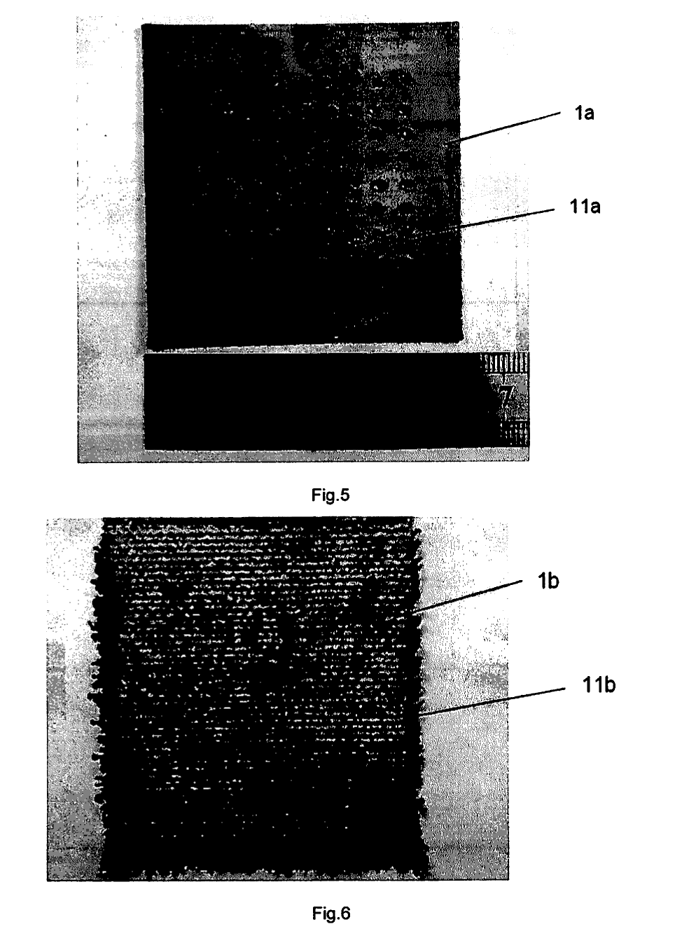

However, the whiskers are not confined to exhibiting these forms. Referring to FIG. 5, the substrate (1a) can be preprocessed (e.g., cutting processes such as drilling, milling, turning, forging, and planning) to produce crystal defects (11a) with burrs on the substrate (1a). Referring to FIG. 6, the edge on the substrate (1b) can be directly used as crystal defects (11b); the primary purpose is to use the crystal defects (11) to induce the electric current to generate the effect of current focusing at that area.

Furthermore, in Step C, the substrate (1) and dendritic crystals (13) are deposited with an antioxidant layer (14) to prevent the substrate (1) and dendritic crystals (13) from oxidizing.

Referring to FIG. 8, the present invention provides a purpose and method for using dendritic crystals for directional heat transfer, as follows:

A. It provides the aforementioned dendritic crystals for providing directional heat transfer.

B. Subsequently, the substrate of the aforementioned dendritic crystals for providing directional heat transfer is connected to a heat source (A) to transfer the heat from the heat source through the substrate (1) to the main branch (131) and sub-branch (132) of the aforementioned dendritic crystals (13). Furthermore, the aforementioned dendritic crystals (13) can be placed by a heat source (A) to transfer the heat from the heat source (A) through the dendritic crystals (13) to the substrate (1). The embodiment of the use of the dendritic crystals for providing direction heat transfer is described below according to the experiment of the present invention.

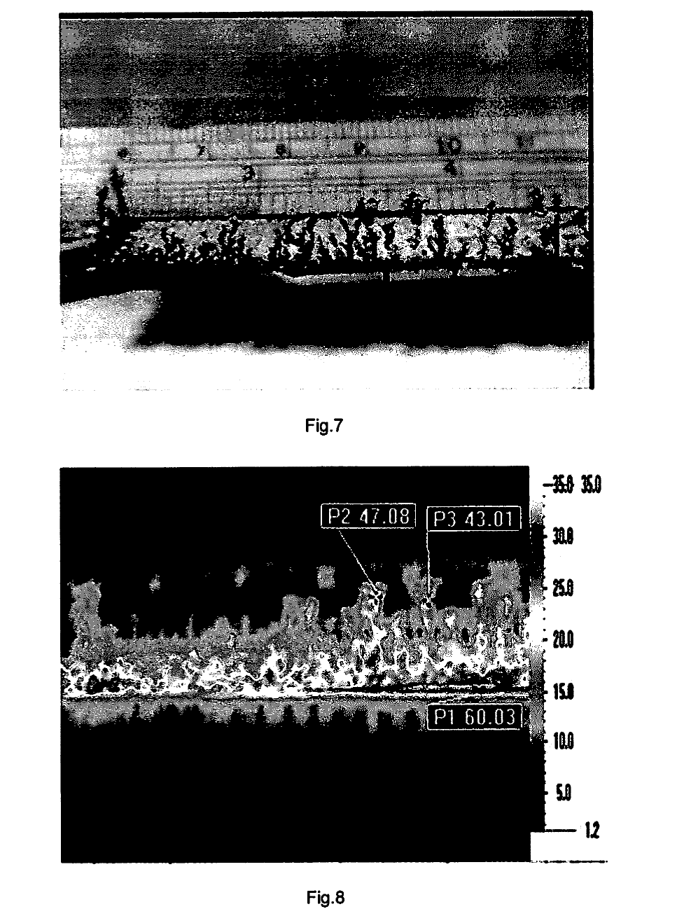

FIGS. 7 and 8 illustrate the appearance of the actual sample and the thermal imaging of the actual sample showing the heat transfer effect of the dendritic crystals (13). Three regions are obtained from FIG. 7 to analyze the temperature changes. Referring to Table 1 and observing Region 1 reveals that when the dendritic crystals are overly packed, temperature accumulates easily; thus, the terminal end of the dendritic crystals in Region 1 has a temperature of 47.08° C., which is higher than that of other tree-like crystals. Region 2 is at the vicinity of the heat source; thus, heat accumulation caused a high temperature in the surrounding area of Region 2. Region 3 contains a single dendritic crystal; the temperature around the heat source is 49.91° C., and the temperature of the terminal end reduced to 32.01° C., thus preliminarily indicating that dendritic crystals facilitate heat dissipation.

TABLE 1
A comparison of the temperature on the thermal regions containing
dendritic crystals growing from the microtiter plates.

| | Average | Maximum | Minimum |
|---|---|---|---|
| | Temperature | Temperature | Temperature |
| Region | (° C.) | (° C.) | (° C.) |
| 1 | 41.78 | 47.08 | 32.34 |
| 2 | 53.81 | 60.03 | 47.39 |
| 3 | 40.93 | 49.91 | 32.01 |

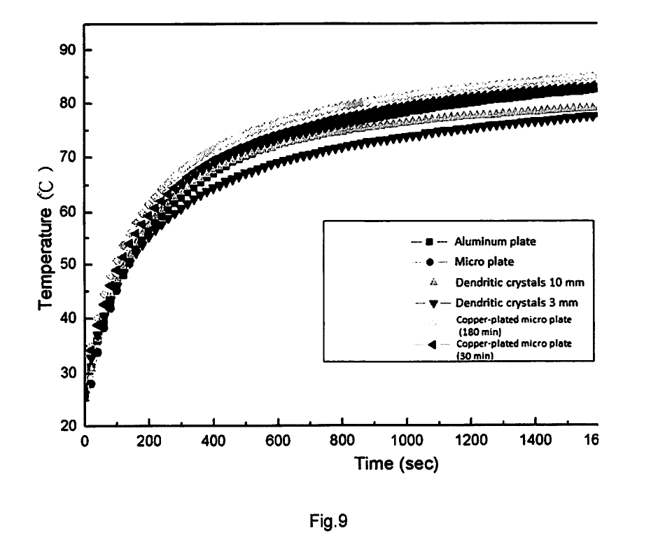

FIG. 9 is a graph showing a comparison of the temperatures of various test specimens and the dendritic crystals of the present invention exposed to the same heat source (LED light) for 30 minutes. In particular, the test specimen included pure aluminum plate, micro plate, and copper-plated micro plate. The dendritic crystals of the present invention comprise 3-mm tall tree-like dendritic crystals grown on the microtiter plates and 10-mm tree-like dendritic crystals grown on the microtiter plates.

Observations show that at 30 min, the 3-mm dendritic crystals had the lowest temperature (78.4° C.) and the 10-mm dendritic crystals had the secondary high temperature (79.6° C.). In addition, the heat dissipation effect of the copper-plated microtiter plates is inferior to that of pure microtiter plates, exhibiting a temperature of 85.7° C. and 83.9° C., respectively.

Table 2 presents the thermal resistance and heat transfer coefficient calculated for the dendritic crystals of the present invention and various test specimens. The thermal resistance values of the aluminum plate and microtiter plates are 12.35 and 12.10° C./W, respectively; the thermal resistance values of the micro plate with 3-mm and 10-mm dendritic crystals are 9.90 and 9.58° C./W, respectively. The thermal resistance values of the copper-plated micro plate at 30 min and 180 min are 10.55 and 11.50° C./W, respectively. Comparing the thermal resistance values reveal that the thermal resistance of the microtiter plates with dendritic crystal growth is relatively lower, specifically that of the microtiter plates with the 10-mm dendritic crystal growth is the best.

TABLE 2
Thermal resistance and heat transfer coefficient for the dendritic
crystals of the present invention and various test specimens.

| | | | Temperature | | |
|---|---|---|---|---|---|
| | | | difference | | |
| | | | between | | |
| | | Heat- | heat- | Heat | Thermal |
| | | dissi- | dissipating | transfer | resis- |
| | Environ- | pating | plate and | coefficient | tance |
| | ment | plate | environment | K | R |
| Specimen | (° C.) | (° C.) | ΔT (° C.) | (W/m*° C.) | (° C./W) |
| Aluminum | 26 | 75.4 | 49.4 | 22.49 | 12.35 |
| plate | | | | | |
| Microtiter | 25.3 | 73.7 | 48.4 | 22.96 | 12.10 |
| plates | | | | | |
| Plate with | 26.3 | 64.6 | 39.3 | 29.01 | 9.58 |
| 10-mm | | | | | |
| dendritic | | | | | |
| crystals | | | | | |
| Plate with | 25.3 | 64.9 | 39.6 | 28.06 | 9.90 |
| 3-mm | | | | | |
| dendritic | | | | | |
| crystals | | | | | |
| Copper- | 25.6 | 67.8 | 42.2 | 26.33 | 10.55 |
| plated | | | | | |
| microtiter | | | | | |
| plates | | | | | |
| (180 min) | | | | | |
| Copper- | 25.9 | 71.9 | 46 | 24.15 | 11.50 |
| plated | | | | | |
| microtiter | | | | | |
| plates | | | | | |
| (30 min) | | | | | |

Below, thermal imaging is used to observe the temperature distribution, further analyzing the heat dissipation of copper dendritic crystals and effective radiation region.

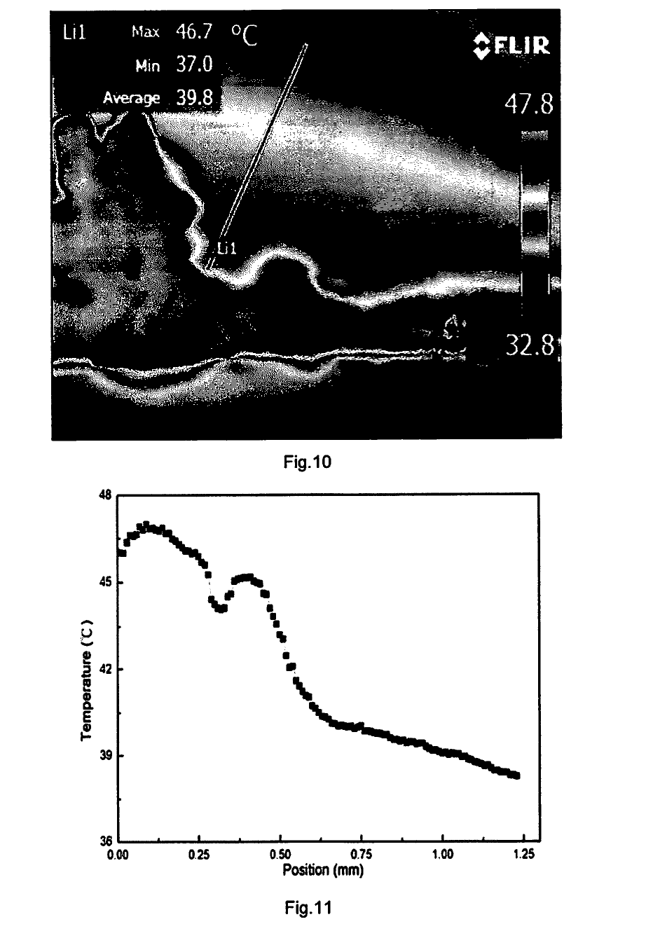

FIG. 10 shows that the surface of dendritic crystals and the environment exhibit temperature difference, which dissipates into the surrounding using a temperature gradient. Referring to FIG. 13, the temperature of the dendritic crystals is 47.8° C., and that of the surface on the dendritic crystals is 46.7° C. As the heat dissipate outward at three positions (namely, 0.38 mm, 0.63 mm, and 1.25 mm), the temperature gradually decreased to 45° C., 39° C., and 37° C., respectively. In addition, the distance between Position 0.38 mm and 0.63 mm and between 0.63 mm and 1.25 mm is 0.25 mm and 0.62 mm, respectively. The ratio of heat removed is 1:1.9:1.17. In FIG. 13, the curve gradually flattened more than Position 0.63, and in FIG. 10, the thermal image of hot air shows no swaying phenomenon caused by air flow, verifying that the experiment was in a windless state. This also indicates that the heat heats the surrounding air from the surface of the dendritic crystals through thermal convection, and cools as it dissipates outward, achieving heat dissipation effect and a high-efficiency heated air thickness of 0.62 mm.

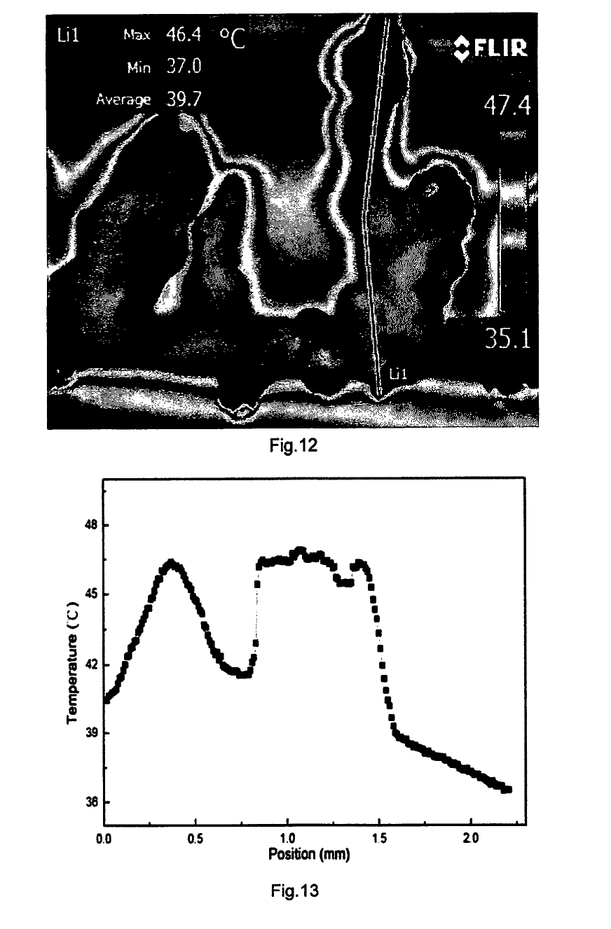

FIG. 12 illustrates the heat transfer occurring in a single dendritic crystal with a length of 2.3 mm. Referring to FIG. 11, at 0.0 mm to 0.5 mm are positions where heat is transferred to the dendritic crystals, and heat dissipates at positions between 0.5 mm and 0.9 mm. Between 1 mm and 1.5 mm, the narrowest area of the dendritic crystal, because this region has limited heat dissipating surface area, heat deposited in this region, hindering heat dissipation. From 1.5 mm to 2.5 mm, the dendritic crystal is broader in width, enabling the deposited heat to dissipate, reducing the overall dendritic crystal temperature from 46.4° C. to 37.0° C., yielding a difference of 9.4° C.

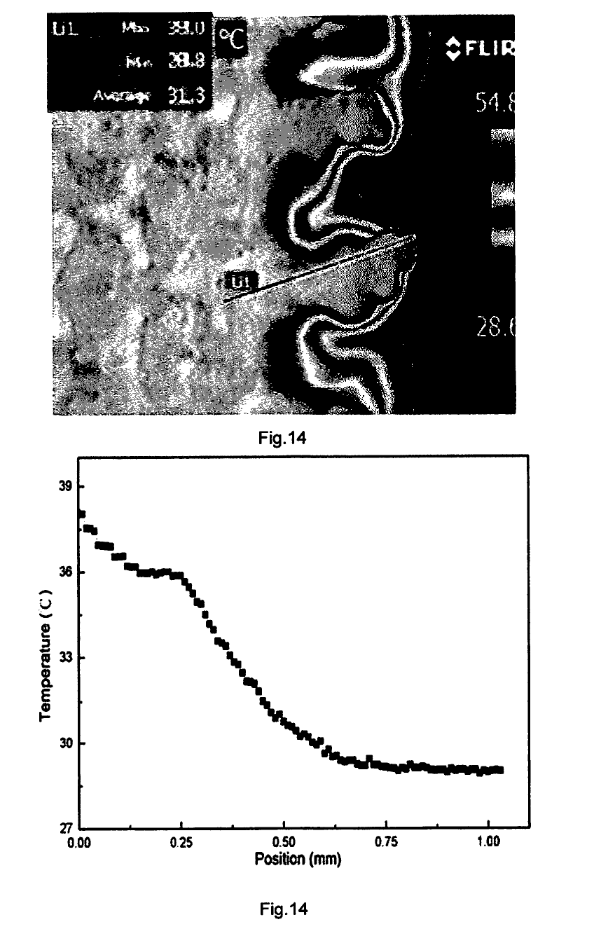

FIG. 14 illustrates the heat transfer occurring in a single dendritic crystal with a length of 0.75 mm. Referring to FIG. 15, the temperature of the dendritic crystal is 38° C. When the heat in the dendritic crystal is transferred to a position between 0.2 mm and 0.3 mm, because the width decreased, the heat deposited in this area, reaching a temperature of 36° C. After 0.3 mm, the temperature on the surface of the dendritic crystal is 28.8° C., subsequently rapidly decreasing between 0.3 mm and 0.75 mm from 36° C. to 28.8° C., reaching a constant temperature after 0.75 mm.

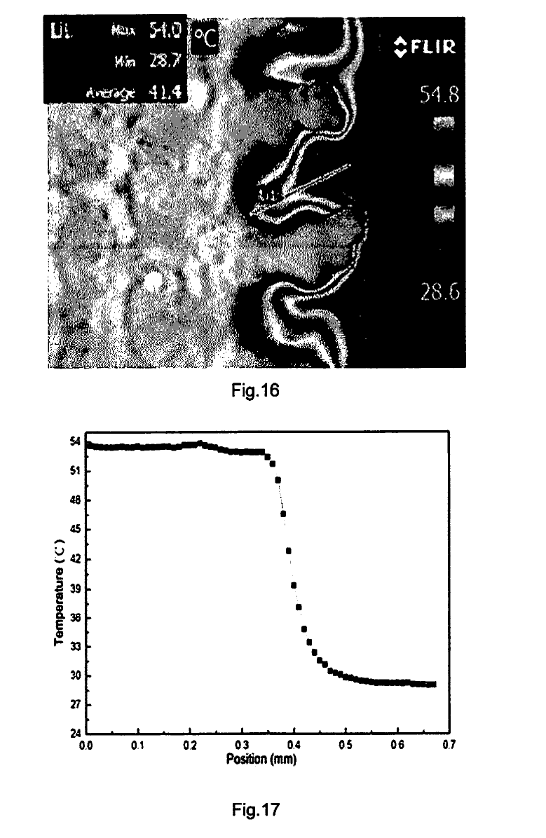

FIG. 16 illustrates the heat transfer occurring in the area between two dendritic crystals. Referring to FIG. 17, the position between 0.35 mm and 0.5 mm is the optimal region for reducing temperature, where temperature decreased from 51° C. to 30° C. and remained constant from 0.5 mm to 0.7 mm. Heat radiation effect is observed at 0.2 mm and no heat deposition is observed between dendritic crystals with a length of 0.75 mm. Accordingly, the two sides of the dendritic crystal should have a space of 2.5 mm for heat transfer. If this space is overly narrow, it will influence the heat transfer region, obstructing the complete dissipation of heat, causing heat deposition. In single dendritic crystal, the width must be consistent; if the width diminishes, the heat deposits in the region, lowering the effect of heat dissipation.

The specifications of the experimental instruments Thermal Imager Camera and Scanning Electron Microscope (SEM) used in the present invention are supplemented below. Thermal Imager Camera employs an infrared (IR) detector and optical image lens to absorb the IR radiation energy of the test object, reflecting the shape of the object onto the photosensitive component of the IR detector, from which IR thermal image is obtained. This image corresponds to the heat distribution of the object. The experiment of the present invention involves using two Thermal Imager Cameras to respectively analyze the phenomenon of heat transfer and thermal convection at the macroscopic and microscopic levels.

TABLE 3
Specifications of the Thermal Image Analyzer used
in the experiment of the present invention.

| | | FLIR SC325 + |
|---|---|---|
| | NEC-F30W | FOL18 |
| Resolution | 160 × 120 | 320 × 240 |
| Measuring range | 20-350° C. | −20-300° C. |
| Manufacturer | Ching Hsing | Precision |
| | Computer-Tech | International |
| | Ltd. | Corp. |
| Analytical model | macroscopic | macroscopic and |
| | | microscopic |

TABLE 4
Specifications of the SEM used in the present invention.

| | |
|---|---|
| Specification | Hitachi S3000N |
| Secondary electron | >3.5 nm (30 kV high vacuum) |
| resolution | >10 nm (3 kV low vacuum) |
| Backscattered electron | >5.0 nm (30 kV, high vacuum) |
| resolution | |
| Magnification | 20X-300,000X |
| Accelerating voltage | 0.5-30 kV |
| Resolution | 640 × 480-5120 × 3840 pixels |

The explanation on the embodiment of the present invention provides a thorough understanding of the operation and use of and the effect generated by the present invention. Nevertheless, the invention has been shown and described with reference to certain preferred embodiments thereof, it will be understood by those skilled in the art that changes in form and details may be made to the content described herein without departing from the concept, spirit, and scope of the invention. All such similar substitutes and modifications are deemed to be within the scope of the invention as defined by the appended claims.

### DESCRIPTION OF SYMBOLS

(1)(1a)(1b) Substrate
(100) Covered whisker layer
(11)(11a)(11b) Crystal defects
(12) Metal layer
(13)(13A)(13B)(13C) Dendritic crystals
(131) Main branch
(132) Sub-branch
(14) Antioxidant layer
(A) Heat source
(D) Spacing

What is claimed:

1. A heat transfer component with dendritic crystals comprising:
a substrate, on which multiple crystal defects with spacing between one another are drilled; and
numerous dendritic crystals, which are deposited on the crystal defects of the substrate, and the aforementioned dendritic crystals possess spacing between one another for thermal convection.

2. The heat transfer component of claim 1, wherein the aforementioned dendritic crystals comprise one main branch to which one sub-branch is connected.

3. The heat transfer component of claim 1, wherein the aforementioned crystal defects comprise any one of or a combination of a whisker, protrusion, burr, and an edge.

4. The heat transfer component of claim 1, wherein the density of the aforementioned dendritic crystals on the substrate is 3-15 dendritic crystal/cm2.

5. The heat transfer component of claim 1, wherein the length of the aforementioned dendritic crystals is 0.1-15 mm.

6. The heat transfer component of claim 1, wherein the length of the aforementioned dendritic crystals is 1-5 mm.

7. The heat transfer component of claim 1, wherein the aforementioned space has a length of 0.1-15 mm.

8. The heat transfer component of claim 1, further comprising an antioxidant layer used to cover the aforementioned substrate and aforementioned dendritic crystals.

9. The heat transfer component of claim 1, wherein the material of the dendritic crystals is copper or copper alloy.

10. The heat transfer component of claim 1, wherein the ratio of the height of the dendritic crystals to the length of the cross-sectional diagonal line is greater than 2.

11. A purpose of dendritic crystals for heat transfer comprising:
least one dendritic crystal on the substrate, and then connecting the aforementioned substrate to a heat source to induce directional heat transfer from the substrate to the dendritic crystal,
or placing the dendritic crystal by a heat source to induce heat transfer from the heat source through the dendritic crystal to the substrate.

12. A method of dendritic crystals for heat transfer comprising:
least one dendritic crystal on the substrate, and then executing the following method:
place the substrate on a heat source to induce heat transfer from the heat source through the substrate to the dendritic crystal,
or place the dendritic crystal by a heat source to induce heat transfer from the heat source through the dendritic crystal to the substrate.
